(19) United States
(12) Patent Application Publication
(10) Pub. No.: US 2025/0132550 A1
(43) Pub. Date: Apr. 24, 2025

(54) APPARATUS FOR BUSBAR CONDUCTION COOLING

(71) Applicant: Enphase Energy, Inc., Petaluma, CA (US)

(72) Inventor: Jarrett Duvall GOODELL, Austin, TX (US)

(21) Appl. No.: 18/911,822

(22) Filed: Oct. 10, 2024

Related U.S. Application Data
(60) Provisional application No. 63/544,994, filed on Oct. 20, 2023.

(51) Int. Cl. H02G 5/10; H05K 7/20

(52) U.S. Cl. CPC H02G 5/10; H05K 7/20445; H05K 7/2049

(57) ABSTRACT

A busbar configured to transport current between two locations in an electrical system is provided herein and comprises a connection extending from the busbar parallel to a direction of current flow and configured so that a thermal interface material of the connection contacts a heat sink when the heat sink is secured to the connection.

### CROSS-REFERENCE TO RELATED APPLICATIONS

The present application claims the benefit of and priority to U.S. Provisional Application Ser. No. 63/544,994, filed on Oct. 20, 2023, the entire contents of which is incorporated herein by reference.

### BACKGROUND

### 1. Field of the Disclosure

Embodiments of the present disclosure generally relate to busbars and, for example, to apparatus for busbar conduction cooling.

### 2. Description of the Related Art

Conventional power conversion systems are known and can comprise a load center that is coupled to a DER (distributed energy resource) by an AC bus such that power conditioners that are coupled to DC batteries convert AC power from the AC bus to DC power for charging the DC batteries. In operation, the busbars can transport significant amounts of current from one location of the power conversion systems to another location of the power conversion systems and can be subject to large resistive heating loads.

The resistive heating loads can sometimes be high enough to require additional cooling mechanisms. For example, conduction cooling with an additional parallel heat path (e.g., parallel to the current flow path) can be used to improve busbar cooling. Contacting the busbar with one or more metals (e.g., copper or aluminum) to remove heat, however, poses several problems. For example, electrical shorts of the busbar can occur if a contacting metal heat sink is not properly insulated. Additionally, galvanic corrosion if dissimilar metals contact each other with no insulator in between the dissimilar metals can also occur. Using screws, washer, and/or nuts can add cost and assembly steps and can also contribute to galvanic corrosion.

Conventional methods and apparatus sometimes use exceptionally large and thick busbars to minimize resistive heating while simultaneously lowering conduction thermal resistance, or can sometimes use screws, nuts, or rivets to create a joint, and use mica/nylon/glass-filled polymer washers or sheets at the joint to separate the heat sink from the busbar. Additionally, one or more coatings can be added to the busbars to improve emissivity of copper, thus lowering the temperature of the busbar. Moreover, one or more fans/blowers can be used to create forced convection over the busbar to increase cooling.

Therefore, described herein are improved apparatus for busbar conduction cooling.

### SUMMARY

In accordance with some aspects of the present disclosure, there is provided a busbar configured to transport current between two locations in an electrical system. The busbar can comprise a connection extending from the busbar parallel to a direction of current flow and configured so that a thermal interface material of the connection contacts a heat sink when the heat sink is secured to the connection.

In accordance with some aspects of the present disclosure, there is provided a method of manufacturing a busbar configured to transport current between two locations in an electrical system. The method comprises monolithically forming the busbar and a connection using an extrusion process and applying a thermal interface material to an interior surface of the connection.

Various advantages, aspects, and novel features of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIGS. 2A-2D are diagrams of a busbar configured for use with one or more components of the system for power conversion of FIG. 1, in accordance with at least some embodiments of the present disclosure; and

FIG. 3 is a method of manufacturing a busbar configured to transport current between two locations in an electrical system, in accordance with at least some embodiments of the present disclosure.

### DETAILED DESCRIPTION

In accordance with the present disclosure, described herein are improved apparatus for busbar conduction cooling. For example, a busbar configured to transport current between two locations in an electrical system can comprise a connection extending from the busbar parallel to a direction of current flow. The connection can be configured so that a thermal interface material of the connection contacts a heat sink when the heat sink is secured to the connection. The methods and apparatus described herein provide busbars with all the desired benefits of conventional busbars without the need of overly thick busbars, screws, washers, nuts, coatings, etc.

The methods and apparatus described herein are configured for use with one or more busbar configurations that are capable of transporting current between two locations in an electrical system. For illustrative purposes, the methods and apparatus are described herein for use with one or more components of an energy management system.

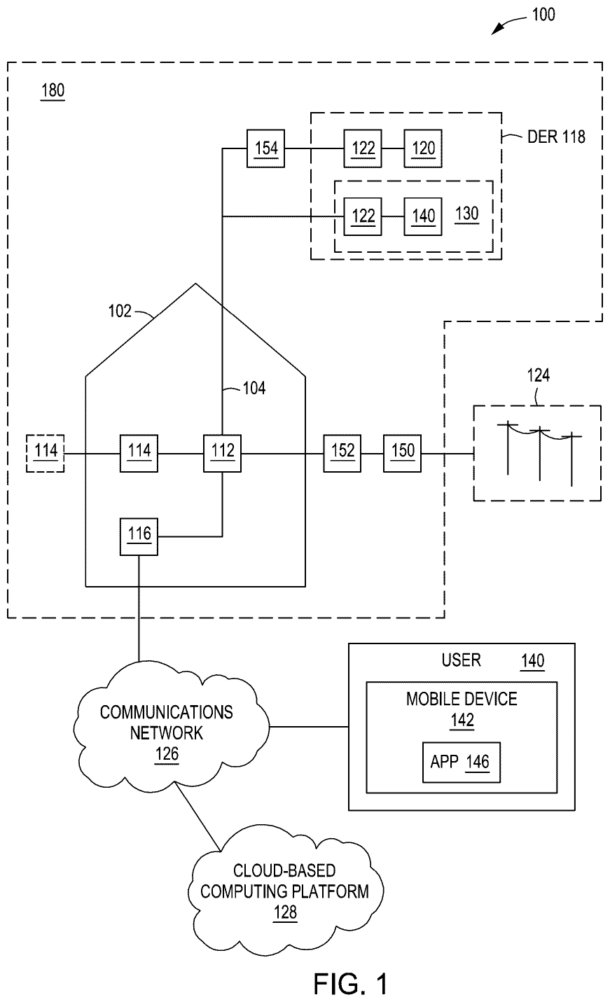

For example, FIG. 1 is a block diagram of an energy management system (e.g., a power conversion system, system 100) in accordance with one or more embodiments of the present disclosure. The diagram of FIG. 1 only portrays one variation of the myriad of possible system configurations. The present disclosure can function in a variety of environments and systems.

The system 100 comprises a structure 102 (e.g., a user's structure), such as a residential home, commercial building, or separate mounting structure, having an associated DER 118 (distributed energy resource). The DER 118 is situated external to the structure 102. For example, the DER 118 may be located on the roof of the structure 102 or can be part of a solar farm. Alternatively, the DER 118 can be situated internal to the structure 102. For example, when the DER 118 is a permanent residential battery energy storage system, the DER 118 may be installed in a garage (or other suitable location inside the structure 102). The structure 102 comprises one or more loads 114 (and/or energy storage devices)—e.g., portable energy systems (PES), appliances, electric hot water heaters, thermostats/detectors, boilers, electric vehicle supply equipment (EVSE), EVs, water pumps, and the like, which can be located within or outside the structure 102—and a DER controller 116, each coupled to a load center 112. Although the one or more loads 114 (and/or energy storage devices), the DER controller 116, and the load center 112 are depicted as being located within the structure 102, one or more of these may be located external to the structure 102.

The load center 112 is coupled to the DER 118 by an AC bus 104 and is further coupled, via a meter 152 and optionally a MID 150 (microgrid interconnect device), to a grid 124 (e.g., a commercial/utility power grid). The structure 102, the one or more loads 114 (and/or energy storage devices), DER controller 116, DER 118, load center 112, generation meter 154, the meter 152, and the MID 150 are part of a microgrid 180. It should be noted that one or more additional devices not shown in FIG. 1 may be part of the microgrid 180. For example, a power meter or similar device may be coupled to the load center 112.

The DER 118 comprises at least one renewable energy source (RES) coupled to power conditioners 122 (e.g., microinverter, power converter, power conversion units (PCUs), etc.). For example, the DER 118 may comprise a plurality of RESs 120 coupled to a plurality of power conditioners 122 in a one-to-one correspondence (or two-to-one). In embodiments described herein, each RES of the plurality of RESs 120 is a photovoltaic module (PV module), although in other embodiments the plurality of RESs 120 may be any type of system for generating DC power from a renewable form of energy, such as wind, hydro, and the like. The DER 118 may further comprise one or more batteries (or other types of energy storage/delivery devices) coupled to the power conditioners 122 in a one-to-one correspondence, where each pair of power conditioner 122 and a DC battery 141 may be referred to as an AC battery 130.

The power conditioners 122 invert the generated DC power from the plurality of RESs 120 and/or the DC battery 141 to AC power that is grid-compliant and couple the generated AC power to the grid 124 via the load center 112. The generated AC power may be additionally or alternatively coupled via the load center 112 to the one or more loads 114 and/or the energy storage devices (e.g., EV, EVSE). In addition, the power conditioners 122 that are coupled to the DC batteries convert AC power from the AC bus 104 to DC power for charging the DC batteries. A generation meter 154 is coupled at the output of the power conditioners 122 that are coupled to the plurality of RESs 120 in order to measure generated power.

In at least some embodiments, the power conditioners 122 may be AC-AC converters that receive AC input and convert one type of AC power to another type of AC power. Alternatively, the power conditioners 122 may be DC-DC converters that convert one type of DC power to another type of DC power. The DC-DC converters may be coupled to a main DC-AC inverter for inverting the generated DC output to an AC output.

The power conditioners 122 may communicate with one another and with the DER controller 116 using power line communication (PLC), although additionally and/or alternatively other types of wired and/or wireless communication may be used. The DER controller 116 may provide operative control of the DER 118 and/or receive data or information from the DER 118. For example, the DER controller 116 may be a gateway that receives data (e.g., alarms, messages, operating data, performance data, and the like) from the power conditioners 122. The DER controller 116 communicates the data and/or other information via the communications network 126 to a cloud-based computing platform 128, which can be configured to execute one or more application software, e.g., a grid connectivity control application, to a remote device or system such as a master controller (not shown), and the like. The DER controller 116 may also send control signals to the power conditioners 122, such as control signals generated by the DER controller 116 or received from a remote device or the cloud-based computing platform 128. The DER controller 116 may be communicably coupled to the communications network 126 via wired and/or wireless techniques. For example, the DER controller 116 may be wirelessly coupled to the communications network 126 via a commercially available router. In one or more embodiments, the DER controller 116 comprises an application-specific integrated circuit (ASIC) or microprocessor along with suitable software (e.g., a grid connectivity control application) for performing one or more of the functions described herein (e.g., the methods described herein).

The generation meter 154 (which may also be referred to as a production meter) may be any suitable energy meter that measures the energy generated by the DER 118 (e.g., by the power conditioners 122 coupled to the plurality of RESs 120). The generation meter 154 measures real power flow (kWh) and, in some embodiments, reactive power flow (kVAR). The generation meter 154 may communicate the measured values to the DER controller 116, for example using PLC, other types of wired communications, or wireless communication. Additionally, battery charge/discharge values are received through other networking protocols from the DC battery itself.

The meter 152 may be any suitable energy meter that measures the energy consumed by the microgrid 180, such as a net-metering meter, a bi-directional meter that measures energy imported from the grid 124 and well as energy exported to the grid 124, a dual meter comprising two separate meters for measuring energy ingress and egress, and the like. In some embodiments, the meter 152 comprises the MID 150 or a portion thereof. The meter 152 measures one or more of real power flow (kWh), reactive power flow (kVAR), grid frequency, and grid voltage. The meter 152 measures power flows independently of MID state, i.e., when MID is closed and DER's are connected to the grid and when MID is open and DER's are isolated from the grid.

The MID 150, which may also be referred to as an island interconnect device (IID), connects/disconnects the microgrid 180 to/from the grid 124. The MID 150 comprises a disconnect component (e.g., a, relay, a contactor, or the like) for physically connecting/disconnecting the microgrid 180 to/from the grid 124. For example, the DER controller 116 receives information regarding the present state of the system from the power conditioners 122, and also receives the energy consumption values of the microgrid 180 from the meter 152 (for example via one or more of PLC, other types of wired communication, and wireless communication). Based on the received information (inputs), the DER controller 116 can determine when to go on-grid or off-grid and instructs the MID 150 accordingly. In some alternative embodiments, the MID 150 comprises an ASIC or CPU, along with suitable software (e.g., an islanding module) for determining when to disconnect from/connect to the grid 124. For example, the MID 150 may monitor the grid 124 and detect a grid fluctuation, disturbance or outage and, as a result, disconnect the microgrid 180 from the grid 124. Once disconnected from the grid 124, the microgrid 180 can continue to generate power as an intentional island without imposing safety risks, for example on any line workers that may be working on the grid 124.

In some alternative embodiments, the MID 150 or a portion of the MID 150 is part of the DER controller 116. For example, the DER controller 116 may comprise a CPU and an islanding module for monitoring the grid 124, detecting grid failures and disturbances, determining when to disconnect from/connect to the grid 124, and driving a disconnect component accordingly. The disconnect component may be part of the DER controller 116 or, alternatively, separate from the DER controller 116. In some embodiments, the MID 150 may communicate with the DER controller 116 (e.g., using wired techniques such as power line communications, or using wireless communication) for coordinating connection/disconnection to the grid 124.

A user 140 can use one or more computing devices, such as a mobile device 142 (e.g., a smart phone, tablet, or the like) communicably coupled by wireless means to the communications network 126. The mobile device 142 has a CPU, support circuits, and memory, and has one or more applications (e.g., a grid connectivity control application (an application 146)) installed thereon for controlling the connectivity with the grid 124 as described herein. The mobile device 142 may run on commercially available operating systems, such as IOS, ANDROID, and the like.

In order to control connectivity with the grid 124, the user 140 interacts with an icon displayed on the mobile device 142, for example a grid on-off toggle control or slide, which is referred to herein as a toggle button. The toggle button may be presented on one or more status screens pertaining to the microgrid 180, such as a live status screen (not shown), for various validations, checks and alerts. The first time the user 140 interacts with the toggle button, the user 140 is taken to a consent page, such as a grid connectivity consent page, under setting and will be allowed to interact with toggle button only after he/she gives consent.

Once consent is received, based on the desired action as entered by the user 140, corresponding instructions can be communicated to the DER controller 116 via the communications network 126 using any suitable protocol, such as HTTP(S), MQTT(S), WebSockets, and the like. The DER controller 116, which may store the received instructions as needed, instructs the MID 150 to connect to or disconnect from the grid 124 as appropriate.

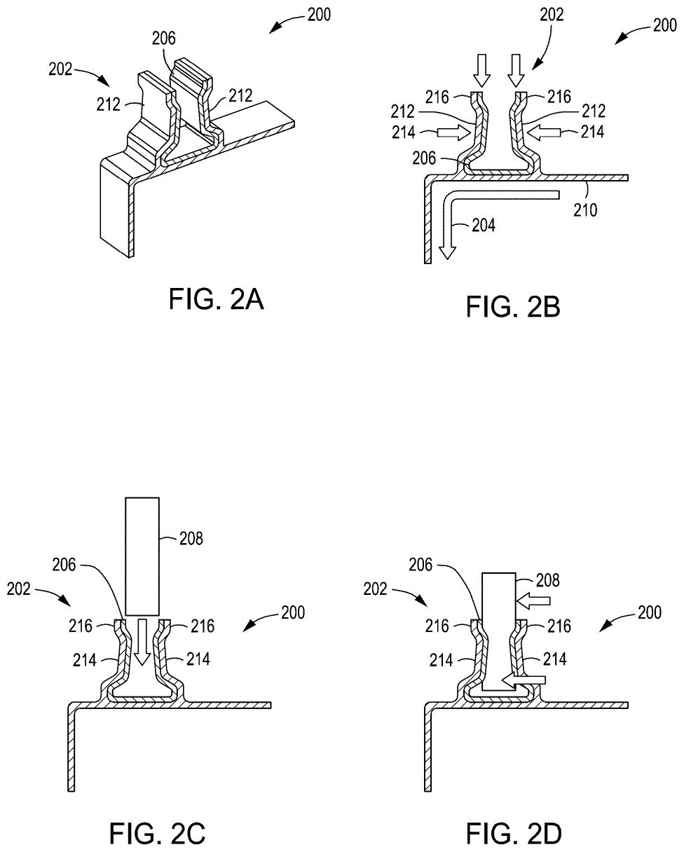

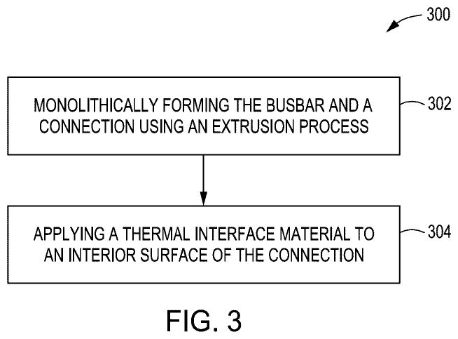

FIGS. 2A-2D are diagrams of a busbar 200 (e.g., the AC bus 104) configured for use with one or more components of the system for power conversion of FIG. 1, and FIG. 3 is a method of manufacturing a busbar configured to transport current between two locations in an electrical system, in accordance with at least some embodiments of the present disclosure.

For example, the busbar 200 can be formed of one or more suitable metals including, but not limited to, aluminum, brass, copper, gold, silver, etc. In the illustrated embodiments, the busbar 200 is formed of one or more metals that are capable of being extruded so that the busbar 200 can be monolithically formed (e.g., formed as one piece) with one or more connections (e.g., formed from aluminum, brass, and/or copper). For example, at 302, the method 300 can comprise monolithically forming the busbar 200 and a connection 202 using an extrusion process.

For example, the connection 202 can be formed to extend from the busbar 200 parallel to the direction of current flow 204. The connection 202 can be configured so that a thermal interface material 206 of the connection 202 contacts a heat sink 208 when the heat sink 208 is secured to the connection 202. For example, in at least some embodiments, the connection 202 can have a generally u-shape with a width that is less than a width of the heat sink 208 for providing a clamping force to the heat sink 208 to secure the heat sink 208 to the busbar 200. For example, the connection 202 can have a base 210 and two opposing sides 212 that comprise medial portions 214 having a generally concave shape that is configured to provide a clamping force when the heat sink 208 is positioned within the connection 202. The two opposing sides 212 have proximal ends 216 that flare out (or widen) from one another to facilitate positioning the heat sink 208 into the connection 202 (e.g., in a generally downward direction, FIG. 2C). Once the heat sink 208 is positioned within the connection 202, the two opposing sides 212 apply a clamping force to the heat sink 208 due to a width of the heat sink 208 being greater than a width between the medial portions 214 of the connection 202 (see FIG. 2D). In an assembled configuration, the heat sink 208 contacts the thermal interface material 206 (at a hot end/portion of the heat sink 208) to draw heat from the busbar 200.

The inventor has found that it is advantageous to have a thermal interface material that is electrically insulative and thermally conductive. With this purpose in mind, in at least some embodiments, the thermal interface material 206 can be at least one of a gap pad (double-sided), a dispensed gel gap filler (or gel pad), or a thermally conductive tape (double-sided). For example, at 304, the method 300 can comprise applying a thermal interface material to an interior surface of the connection 202. In at least some embodiments, such as when the thermal interface material 206 is a gap pad, gel pad, or thermally conductive tape, the thermal interface material 206 can be adhesively bonded to an inner surface of the connection 202, see FIGS. 2A and 2B, for example.

The busbar 200 can be used in place of or in addition to a bus of an electrical system. For example, the busbar 200 can be used in place of the AC bus 104. Alternatively or additionally, the busbar 200 can be connected (brazed, soldered, welded) to the AC bus 104 between one or more loads/components. In at least some embodiments, the busbar 200 can be connected to the AC bus 104 between the load center 112 and the DER 118, between the load center 112 and the one or more loads 114 and/or energy storage devices, between the power conditioners 122 and the AC batteries, etc.

While the foregoing is directed to embodiments of the present disclosure, other and further embodiments of the disclosure may be devised without departing from the basic scope thereof, and the scope thereof is determined by the claims that follow.

1. A busbar configured to transport current between two locations in an electrical system, comprising:
a connection extending from the busbar parallel to a direction of current flow and configured so that a thermal interface material of the connection contacts a heat sink when the heat sink is secured to the connection.

2. The busbar of claim 1, wherein the connection has a generally u-shape with a width that is less than a width of the heat sink for providing a clamping force to the heat sink to secure the heat sink to the busbar.

3. The busbar of claim 1, wherein the thermal interface material is at least one of a gap pad, a gel gap filler, or a thermally conductive tape.

4. The busbar of claim 1, wherein the thermal interface material is electrically insulative and thermally conductive.

5. The busbar of claim 1, wherein the thermal interface material is adhesively bonded to an inner surface of the connection.

6. The busbar of claim 1, wherein the connection is monolithically formed with the busbar using an extrusion process.

7. A method of manufacturing a busbar configured to transport current between two locations in an electrical system, comprising:
monolithically forming the busbar and a connection using an extrusion process; and
applying a thermal interface material to an interior surface of the connection.

8. The method of claim 7, wherein the connection has a generally u-shape with a width that is less than a width of a heat sink for providing a clamping force to the heat sink to secure the heat sink to the busbar.

9. The method of claim 7, wherein the thermal interface material is at least one of a gap pad, a gel, or a thermally conductive tape.

10. The method of claim 7, wherein the thermal interface material is electrically insulative and thermally conductive.

11. The method of claim 7, wherein the thermal interface material is adhesively bonded to an inner surface of the connection.
